(19) United States
(12) Patent Application Publication
(10) Pub. No.: US 2013/0181198 A1
(43) Pub. Date: Jul. 18, 2013

(54) POLYMERS, OPTICAL FILMS, ORGANIC ELECTROLUMINESCENT DEVICES, AND METHODS OF MANUFACTURING THE OPTICAL FILM

(71) Applicant: Electronics and telecommunications Research Institute, Daejeon (KR)

(72) Inventors: Seung Koo PARK, Daejeon (KR); Jeong Ik Lee, Gyeonggi-do (KR); Jaehyun Moon, Daejeon (KR)

(73) Assignee: Electronics and telecommunications Research Insititute, Daejeon (KR)

(21) Appl. No.: 13/736,127

(22) Filed: Jan. 8, 2013

(30) Foreign Application Priority Data
Jan. 18, 2012 (KR) 10-2012-0005621

(51) Int. Cl. H01L 51/00; H01L 51/52

(52) U.S. Cl. CPC H01L 51/0035; H01L 51/5275
USPC 257/40; 525/389

(57) ABSTRACT

Disclosed are polymers, optical films, organic electroluminescent devices, and methods of manufacturing the optical film. The polymer and the optical film according to the inventive concept may include a high refractive material chemically combined with a polymer matrix and a low refractive material chemically combined with the polymer matrix. The low refractive material has a lower refractive index than the high refractive material. Thus, the polymer and the optical film may function as a light scattering layer including the low and high refractive materials chemically combined with the polymer matrix, or a light scattering layer including a high refractive film and low refractive particles dispersed within the high refractive film.

### CROSS-REFERENCE TO RELATED APPLICATIONS

This U.S. non-provisional patent application claims priority under 35 U.S.C. §119 to Korean Patent Application No. 10-2012-0005621, filed on Jan. 18, 2012, the entirety of which is incorporated by reference herein.

### BACKGROUND

The inventive concept relates to polymers, optical films, organic electroluminescent devices, and methods of manufacturing the optical film and, more particularly, to polymers capable of improving light extraction efficiency, optical films including the same, organic electroluminescent devices applied with the same, and methods of manufacturing the optical film.

An organic light emitting diode being an example of organic electroluminescent devices may include an anode, a cathode, and an organic light emitting layer disposed between the anode and the cathode. Holes supplied from the anode may be combined with electrons supplied from the cathode in the organic light emitting layer to form excitons, and then the excitons may be recombined to emit light. The organic light emitting diode may be a self-illuminated device. The organic light emitting diode has been developed to be applied to display devices because of a wide viewing angle, high response speed, and high color reproduction range thereof. The organic light emitting diode may emit light having one of a red (R) color, a green (G) color, and a blue (B) color or emit light of a white color.

According to Thompson, an external energy efficiency showing light emitting efficiency of the organic electroluminescent device may be represented as a value obtained by multiplying an internal energy efficiency of the device and an light extraction efficiency, and light may be total-reflected by an interface between layers of which refractive indexes are different from each other and then be confined in each of the layers, so that the external energy efficiency may be equal to or less 20% (Optics Letters 22, 6, 396, 1997). In other words, the external energy efficiency does not exceed 20%. The light confined and guided in each of the layers of the organic light emitting diode is called ‘a guided mode light’. Light outputted to external air through the interface of the layers is called ‘an output mode light’. Light extraction means that the guided mode light is converted into the output mode light outputted outside in a plane light source device having a panel-shape.

For increasing the light extraction efficiency, an refractive index of a layer relatively close to a light emitting surface of the device may be equal to or higher than that of a layer relatively far away from the light emitting surface. However, a transparent substrate (e.g., a glass substrate) used for emitting light has a low refractive index of about 1.5, such that various problems may occur.

FIG. 1 is a schematic view illustrating a stack structure of a general organic electroluminescent device. As illustrated in FIG. 1, an organic light emitting diode may include a substrate 10, an anode 20 being a transparent electrode, an organic light emitting layer 30, a cathode 40 being a reflecting electrode, and a passivation layer 50 which are sequentially stacked.

In the general organic light emitting diode, a portion of light generated from the organic light emitting layer 30, which is outputted toward the cathode 40, may be mostly reflected by the cathode 40 and then travel toward the anode 20. Thus, the generated light may be mostly outputted toward the anode 20. Here, the substrate 10 may use the glass substrate having a transparent property in the organic light emitting diode having the anode 20 stacked on the substrate 10 for emitting the light. When the light is outputted through the organic light emitting layer 30, the anode 20, and the substrate 10 into air, reflected light \hat{1}, reflected light \hat{2}, and reflected light\hat{3} may occur at an interface between the organic light emitting layer 30 and the anode 20, an interface between the anode 20 and the substrate 10, and an interface between the substrate 10 and the air, respectively, by differences between refractive indexes of the organic light emitting layer 30, the anode 20, the substrate 10, and the air. Particularly, when lights are incident from a medium having a high refractive index on a medium having a low refractive index with an angle equal to or greater than a critical angle with respect to a vertical line (i.e., a normal line) to a top surface of the substrate 10, the lights may be total-reflected and then be extinct in the device by Snell's law represented as the following equation 1.

$$\frac{{n}_{1}}{{n}_{2}} = \frac{sin {a}_{2}}{sin {a}_{1}} \qquad [ Equation 1 ]$$

where, “n₁” denotes an refractive index of a first medium, “n₂” denotes an refractive index of a second medium, “a₁” denotes an incidence angle with respect to the normal line, and “a₂” denotes an refraction angle with respect to the normal line.

The light is incident from the first medium on the second medium. A visible ray-refractive index of the organic light emitting layer 30 may be varied depending on a wavelength of light and may be within a range of 1.6 to 1.9. Generally, a refractive index of indium-tin-oxide (ITO) used as the anode is within a range of 1.9 to 2.0, such that the total-reflection between the organic light emitting layer 30 and the anode 20 may hardly occur. However, the glass or plastic transparent substrate 10 has the refractive index of about 1.5, such that the light generated from the organic light emitting layer 30 may be mostly converted into the guided mode light and then may not be outputted outside if each of the organic light emitting layer 30 and the anode 20 has a thin thickness within a range of 100 nm to 400 nm. This is because the light generated from the organic light emitting layer 30 may be mostly incident on the substrate 10 having the low refractive index in a direction substantially parallel to the top surface of the substrate 10. Thus, the amount of light \hat{4} outputted from the glass substrate 10 may be about 20% of the entire light generated from the organic light emitting layer 30.

As described in the equation 1, if the refractive indexes of the mediums at both side of the interface are equal to each other, the incidence angle is equal to the refraction angle, so that the total reflection does not occur. In other words, if the refractive indexes of the organic light emitting layer 30 and the anode 20 are equal or similar to the refractive index of the substrate 10, it is possible to minimize occurrence of the guided mode by the total reflection at the interface between the substrate 10 and the anode 20. Thus, the light extraction efficiency and a power efficiency of the organic light emitting diode may increase.

However, since the refractive index of the ITO generally used as the anode 20 is within the range of 1.9 to 2.0, it is difficult to find a substrate-material having a refractive index equal or similar to the anode 20. Additionally, since the organic light emitting diode generally emits the light toward the anode 20, the substrate-material should have a high transmittance with respect to the visible ray region. Thus, it is difficult to fine the transparent substrate-material having the refractive index within the range of 1.9 to 2.0, a suitable hardness for the substrate, and a suitable surface smoothness. Even though the substrate-material satisfying the above properties exists, it is difficult to manufacture a thin, flat, and wide substrate having a plate glass-shape with the substrate-material.

Thus, light extraction structures, which are easily manufactured with low manufacture costs, may be needed for forming high efficiency organic electroluminescent devices in quantity.

### SUMMARY

Embodiments of the inventive concept may provide polymers capable of improving light extraction efficiency, optical films including the same, and organic electroluminescent devices applied with the same.

In an aspect, a polymer may include: a polymer matrix; a high refractive material chemically combined with the polymer matrix; and a low refractive material chemically combined with the polymer matrix and having a lower refractive index than the high refractive material. All of the low and high refractive materials are chemically combined with the polymer matrix.

In another aspect, an optical film may be formed of the polymer.

In some embodiments, the low refractive material may be separated from the polymer matrix at a temperature lower than a temperature at which the high refractive material is separated from the polymer matrix.

In still another aspect, an organic electroluminescent device may include: an organic light emitting layer; and a film layer increasing light extraction efficiency of light emitted from the organic light emitting layer. The film layer may include a high refractive material and a low refractive material. The high refractive material may be chemically combined with a polymer matrix and have a refractive index equal to or greater than a refractive index of the organic light emitting layer; and the low refractive material may be chemically combined with the polymer matrix and have a refractive index lower than the refractive index of the high refractive material.

In some embodiments, the low refractive material of the film layer may be separated from the polymer matrix by a thermal treating process performed after coating the film layer.

In even another aspect, a method of manufacturing an optical film may include: chemically combining a high refractive material with diamine in polyamic acid being a precursor of polyimide; and chemically combining a low refractive material having a lower refractive index than the high refractive material with carboxylic acid of dianhydride in the polyamic acid.

In yet another aspect, a method of manufacturing an optical film may include: chemically combining a high refractive material with diamine; reacting the diamine with dianhydride to form a polymer; and chemically combining a low refractive material having a lower refractive index than the high refractive material with carboxylic acid of a dianhydride part of polyamic acid being the polymer.

### BRIEF DESCRIPTION OF THE DRAWINGS

The inventive concept will become more apparent in view of the attached drawings and accompanying detailed description.

FIG. 1 is a schematic view illustrating a stack structure of a general organic electroluminescent device;

FIG. 2 is a schematic view illustrating a molecular structure of an optical film according to embodiments of the inventive concept;

FIG. 3 is a schematic view illustrating a molecular structure of a polymer and an optical film including the same according to some embodiments of the inventive concept;

FIG. 4 is a schematic view illustrating a molecular structure of a thermally treated optical film according to some embodiments of the inventive concept;

FIG. 5 is a schematic view illustrating an organic electroluminescent device according to embodiments of the inventive concept;

FIGS. 6A to 6C are schematic views illustrating a method of manufacturing a polymer for an optical film according to embodiments of the inventive concept.

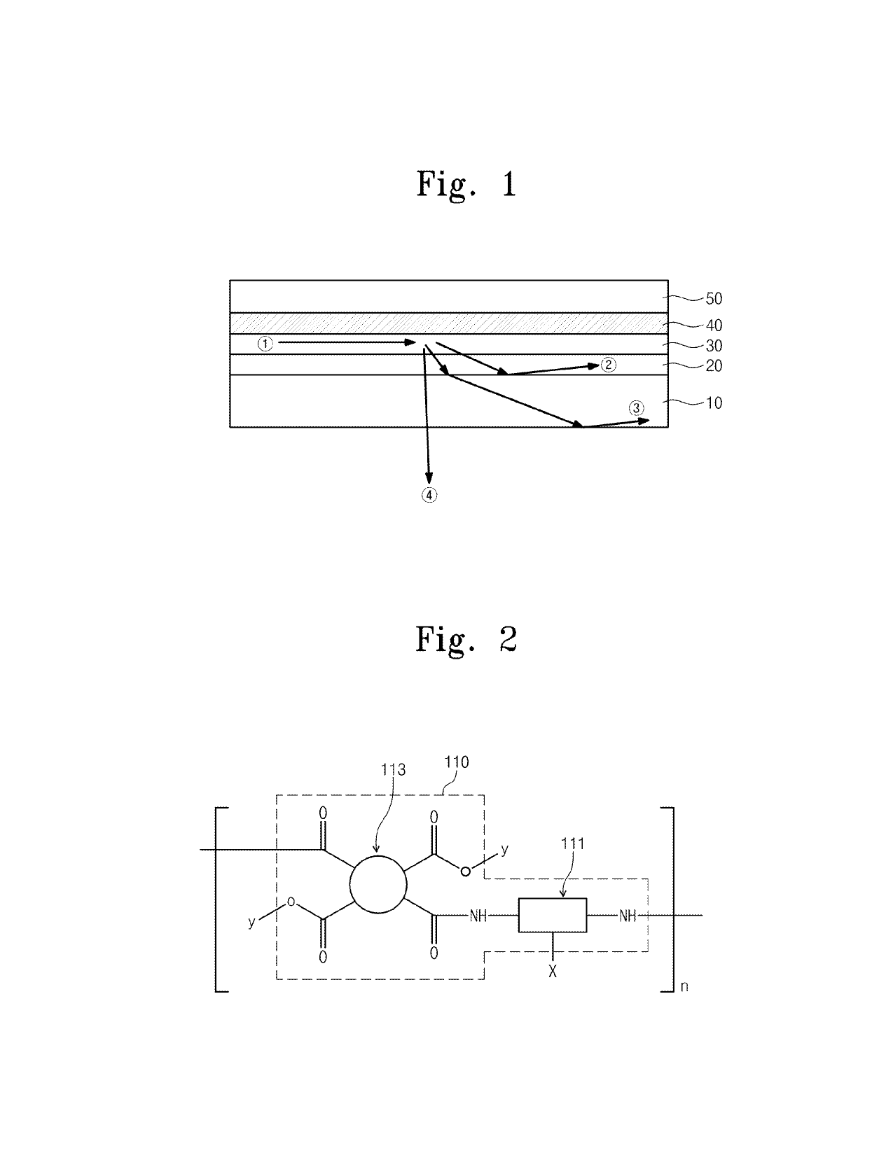

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

FIG. 2 is a schematic view illustrating a molecular structure of an optical film according to embodiments of the inventive concept.

A polymer material (i.e., a polymer compound) and an optical film illustrated in FIG. 2 includes a polymer matrix 110, a high refractive material x chemically combined with the polymer matrix 110, and a low refractive material y chemically combined with the polymer matrix 110 and having a lower refractive index than the high refractive material x. Both the high refractive material x and the low refractive material y are chemically combined with the polymer matrix 110. Here, “n” is within a range of 1 to 1000.

The polymer matrix 110 is a basic compound constituting the optical film. A circle ◯ in the polymer matrix 110 of FIG. 2 may be a cyclic aliphatic or an aromatic. A quadrilateral □ in the polymer matrix 110 of FIG. 2 may be an aliphatic or an aromatic. For example, the polymer matrix 110 may consist of polyamic acid being a precursor of polyimide. The polyimide may be a high heat resistant engineering plastic which is manufactured using the polyamic acid formed by reaction of diamine with dianhydride.

The optical film according to the inventive concept includes the polymer matrix 110, the high refractive material x, and the low refractive material y. External light may be easily inputted into the optical film by the high refractive material x and the inputted light may be scattered by the low refractive material y.

For maximizing the above effects, the optical film may be stacked on an organic electroluminescent device and then the low refractive material y may be separated from the polymer matrix 110. At this time, only the low refractive material y may be separated from the polymer matrix 110 by one thermal treating process or one chemical reaction. The high refractive material x maintains the combined state with the polymer matrix 110, so that the optical film may entirely have a high refractive index and light scattering particles of the low refractive material y may be formed in the optical film. As a result, it is possible to form a light scattering layer capable of improving the light extraction efficiency of the organic electroluminescent device.

Th achieve this, the high refractive material x may be chemically connected to a diamine part 111 in the polyamic acid corresponding to the precursor of polyimide, and the low refractive material y may be chemically connected to a carboxylic acid of a dianhydride part 113 in the polyamic acid. The polyamic acid may be esterified by the chemical combination of the low refractive material y. The esterified low refractive material y chemically combined with carboxylic acid may break away at a high temperature, so that the polyamic ester may be converted into polyimide. The high refractive material x is stably chemically combined with the diamine during the process converting the polyamic ester into the polyimide, thereby forming a composite material including the polyimide having a high refractive index and the light scattering particles dispersed in the polyimide. The light scattering particles have a low refractive index. In this case, it is possible to obtain the high refractive optical film including the light scattering particles formed of the low refractive material by one thermal treating process or one chemical reaction. The high refractive optical film including the light scattering particles may function as a light scattering layer in the organic electroluminescent device.

In the light extraction of the organic electroluminescent device, an internal light extraction may mean a technique extracting light isolated in an organic light emitting/an anode by difference between refractive indexes of the anode and a substrate to the outside of the organic electroluminescent device, and an external light extraction may mean a technique extracting light isolated in the substrate to the outside (air) of the organic electroluminescent device.

The light scattering layer according to the inventive concept may be applied to the internal light extraction and the external light extraction.

Since the light scattering layer does not cause color variation by a view angle and the light scattering layer may basically realize Lambertian light distribution, brightness of a panel may be substantially uniform. Additionally, for forming the light scattering layer, particles having an refractive index greatly different from that of the polymer matrix 110 may be dispersed in the polymer matrix 110 and then the polymer matrix 110 including the particles may be deposited on a glass substrate. Thus, the forming process of the light scattering layer may be relatively simplified. Thus, the light scattering layer may increase the light extraction efficiency, decrease the color variation by the view angle, and realize light distribution closer to the Lambertian light distribution. However, the number of scattering centers should sufficiently increase for increasing the light scattering effect, but back scattering effect may increase by increasing the number of the scattering centers. Thus, the increase of the scattering centers may increase a probability that the scattering light is reabsorbed in the organic light emitting layer. Additionally, the light may also be absorbed in the light scattering layer, so that the light extraction efficiency may be reduced. Thus, it is preferable that an absorption coefficient of the light scattering layer with respect to a visible ray is small for applying the light scattering layer to the internal light extraction structure.

As described above, the difference between the refractive indexes of the matrix and the light scattering particle should be great, and the absorption coefficient of the light scattering layer should be small. The polymer and/or the optical film according to the inventive concept may satisfy the above conditions.

The high refractive material x may include at least one of TiO₂, ZrO₂, ZnO, SnO₂, In₂O₃, and In₂O₃—SnO₂. If the optical film according to the inventive concept is applied to the organic electroluminescent device such as an organic light emitting diode (OLED), the refractive index of the high refractive material x may be greater than that of the organic light emitting layer in order that guided mode light does not occur when the light is transmitted from a material having a low refractive index to a material having a high refractive index.

If the refractive index of the organic light emitting layer is within a range of about 1.6 to about 1.9, the refractive index of the high refractive material x may be equal to or greater than about 1.9. If the optical film is coated stacked on the anode disposed under the organic light emitting layer and a refractive index of the anode is within a range of about 1.9 to about 2.0, the refractive index of the high refractive material x may be equal to or greater than about 2.0. However, through an experiment, it was confirmed that the guided mode light was not generated even if the refractive material x had the refractive index of about 1.8 or more. It is presumed that this is because the light scattering effect also occurs at a non-flat interface caused by a non-flat surface of the organic light emitting layer or a non-flat surface of the anode. A refractive index of a material satisfying the above refractive index condition and having a transmittance needed by the organic electroluminescent device may hardly exceed about 2.5. As a result, the refractive index of the high refractive material x may have a range of about 1.8 to about 2.5.

The high refractive material x may include at least one of other materials satisfying the above refraction conduction and the transmittance needed by the organic electroluminescent device except TiO₂, ZrO₂, ZnO, SnO₂, In₂O₃, and In₂O₃—SnO₂.

The low refractive material y may include SiO₂. The low refractive material y may be formed into the scattering particles for scattering the light inputted into the optical film. The scattering particles should have the refractive index smaller than that of a material (i.e., the polymer matrix 110) surrounding the scattering particles. The scattering particles may be combined with the polymer matrix 110. However, it is preferable that the scattering particles break away from the polymer matrix 110. The low refractive material y detached from the polymer matrix 110 may have random sizes and be randomly mixed with the polymer matrix in the film. Thus, the polymer according to the inventive concept may be more suitable to the function of the light scattering layer.

The low refractive material y may break away from the polymer matrix 110 at a temperature lower than a temperature at which the high refractive material x may break away from the polymer material 110. To achieve this, the low refractive material y may be chemically combined with the carboxylic acid of the dianhydride to be esterified if the polymer matrix 110 is the polyamic acid being the precursor of the polyimide, such that the esterified low refractive material y may break away from the basic film (i.e., the polymer matrix 110) through a thermal or chemical imidization reaction.

Each of the polymer and the optical film described above includes all of the low and high refractive materials y and x, and the low refractive material y may have the combination structure capable of easily breaking away from the polymer matrix 110.

The polymer and the optical film have a structure expressed by the following chemical formula 1. Here, “n” has a range of 1 to 1000.

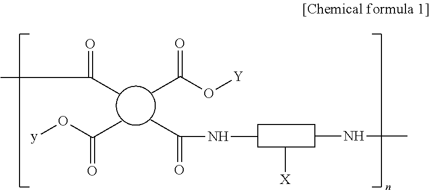

wherein, “x” denotes the high refractive material; and

“y” denotes the low refractive material having a lower refractive index than the high refractive material.

According to the chemical formula 1, the low refractive index y may break away from the polymer matrix at the temperature lower than the temperature at which the high refractive material x may break away from the polymer material.

The high refractive material x may include an inorganic metal oxide transformed from a compound having a structure expressed by the following chemical formula 2.

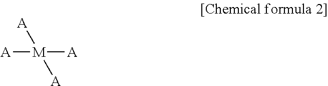

wherein, “A” denotes an alkoxide group capable of being transformed into a hydroxide group by water; and

“M” includes one of Ti, Zr, Zn, Sn, and In.

The M may include one of other inorganic metal elements except Ti, Zr, Zn, Sn, and In described above. The other inorganic metal elements may be transformed into inorganic metal oxides having the high refractive index.

The low refractive material y may include an inorganic metal oxide transformed from a compound having a structure expressed by the following chemical formula 3.

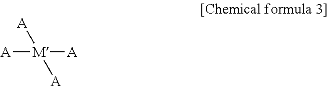

wherein, “A” denotes a alkoxide group capable of being transformed into a hydroxide group by water; and

“M′” denotes Si.

The M′ may include one of other inorganic metal elements except Si. The other inorganic metal elements may be transformed into inorganic metal oxides having the low refractive index.

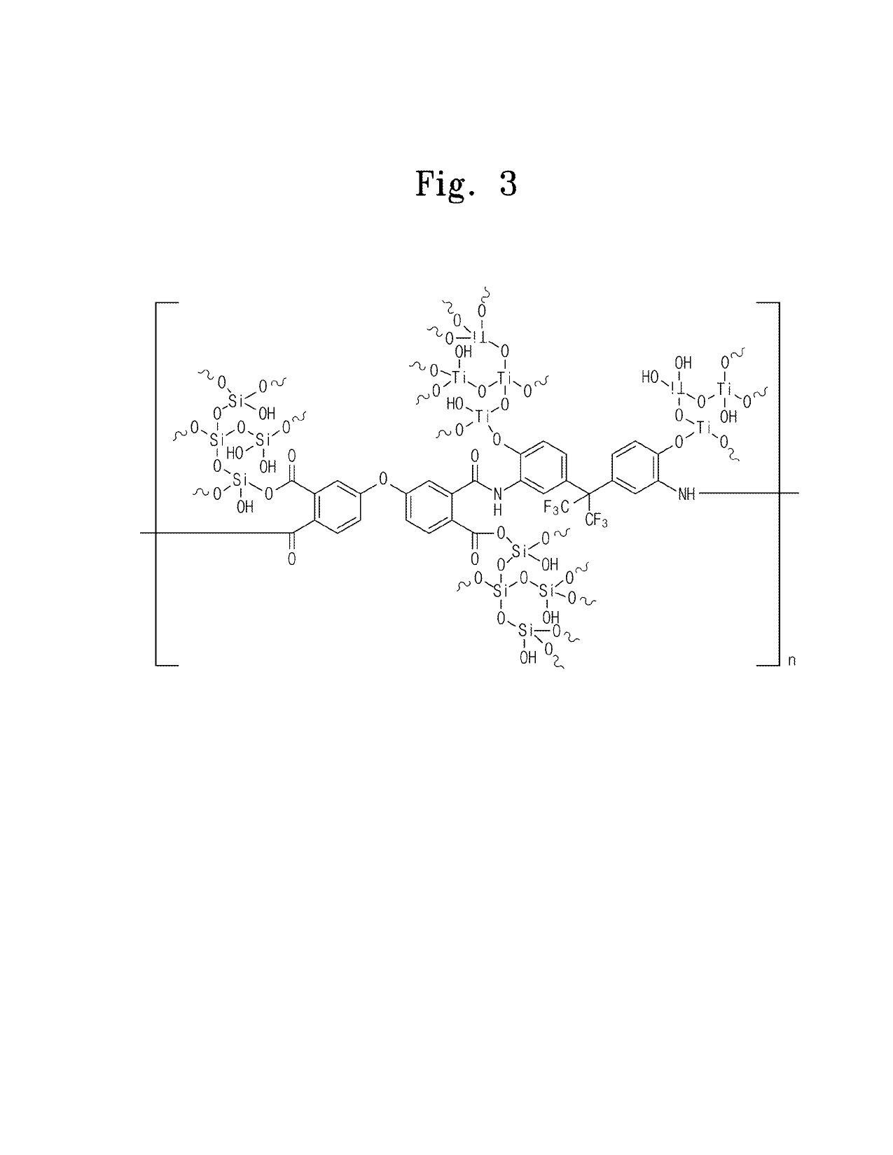

FIG. 3 is a schematic view illustrating a molecular structure of a polymer and an optical film including the same according to some embodiments of the inventive concept. Here, “n” has a range of 1 to 1000.

Referring to FIG. 3, a material including TiO₂ as the high refractive material is chemically combined with the diamine part in the polyamic acid being the precursor of polyimide, and a material including SiO₂ as the low refractive material is chemically combined with the carboxylic acid of the dianhydride part in the polyamic acid.

An optical film having the molecular structure of FIG. 3 includes the high refractive material and the low refractive material therein, so as to perform the function of the light scattering layer. Additionally, the optical film has a structure capable of easily separating SiO₂ from a basic material by a thermal treating process. The separated SiO₂ has a random size and is randomly disposed in the film, so that the optical film may function as the light scattering layer with reliability.

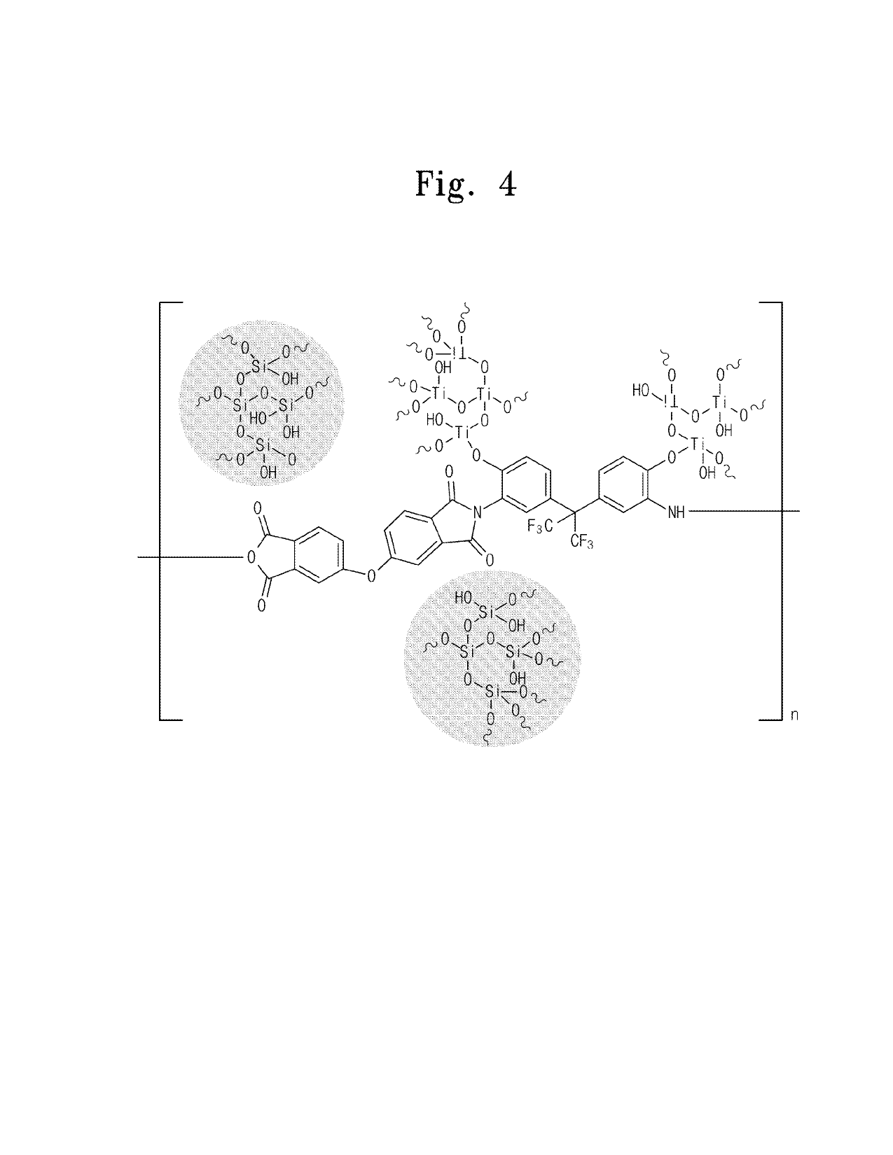

After the optical film of FIG. 3 may be thermally treated, a molecular structure of the thermally treated the optical film is illustrated in FIG. 4. Here, “n” has a range of 1 to 1000. SiO₂ particles formed of the material including SiO₂ being the low refractive material naturally break away from the basic film by the thermal treatment for transforming the polyamic ester into the polyimide.

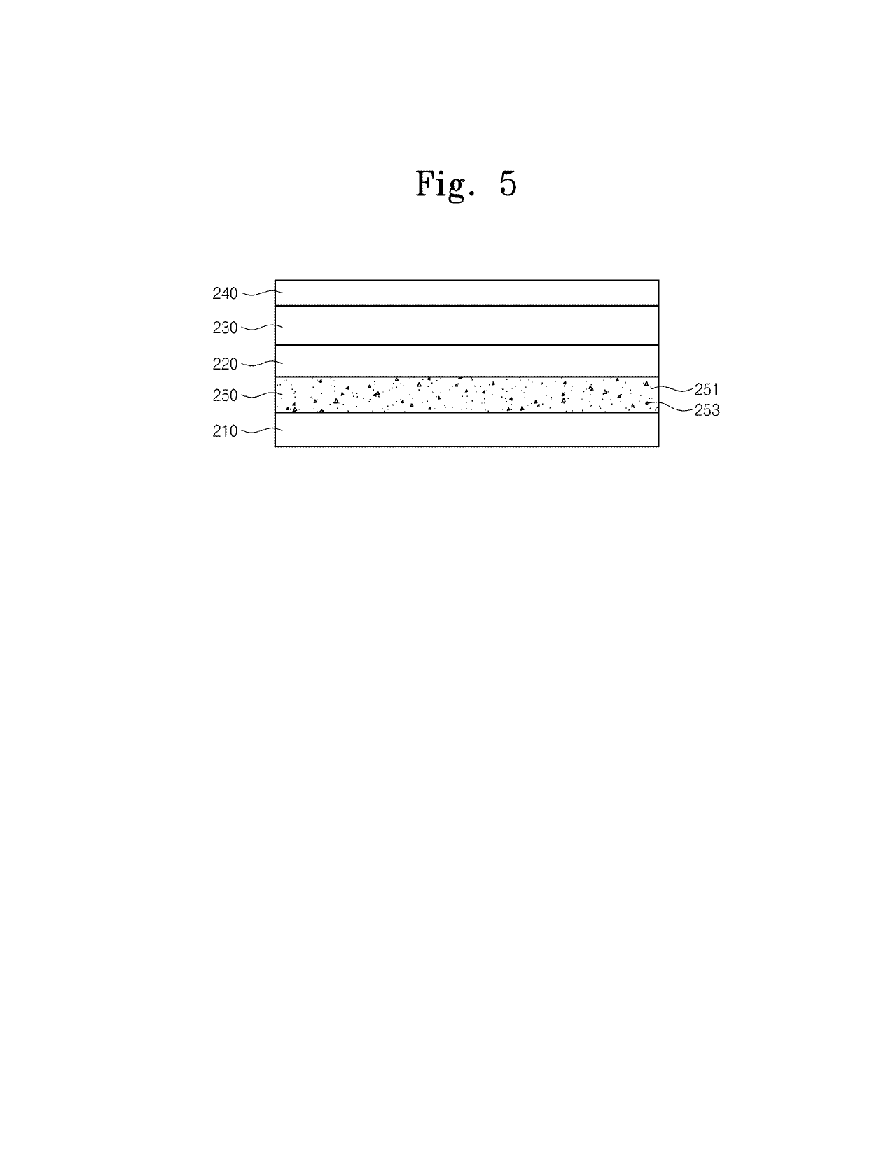

An example of organic electroluminescent devices including the optical film described above is illustrated in FIG. 5.

FIG. 5 is a schematic view illustrating an organic electroluminescent device according to embodiments of the inventive concept.

The organic electroluminescent device illustrated in FIG. 5 includes an organic light emitting layer 230 and a film layer 250 for increasing the light extraction efficiency of light generated from the organic light emitting layer 230.

FIG. 5 shows the organic electroluminescent device including a substrate 210, the film layer 250, an anode 220, the organic light emitting layer 230, and a cathode 240 which are sequentially stacked, as an example.

The substrate 210 may provide a physical hardness of the organic electroluminescent device and function as a transparent window. The substrate 210 may be formed of glass or plastic having a property transmitting light. The plastic may include at least one of polyethylene terephthalate (PET), polycarbonate (PC), polyethersulfone (PES), and polyimide (PI). In other embodiments, the substrate 210 may be omitted, and the film layer 250 may function as the substrate 210.

The anode 220 may be a transparent electrode formed of indium-Tin-oxide (ITO).

The cathode 240 may be formed of a metal thin layer and reflect the light generated from the organic light emitting layer 230 toward the substrate 210.

The organic light emitting layer 230 including an organic material may be an element generating the light by a power applied to the anode 220 and the cathode 240. For example, when an electric field is applied between the anode 220 and the cathode 240, electrons and holes are recombined with each other to output energy and to generate light of a specific wavelength. In some embodiments, the anode 220, a hole injecting layer, a hole transport layer, a light emitting layer, an electron transport layer, an electron injecting layer, and the cathode 240 may be sequentially stacked on the substrate 210. Here, the hole injecting layer, the hole transport layer, the light emitting layer, the electron transport layer, and the electron injecting layer between the anode 220 and the cathode 240 may be defined as the organic light emitting layer 230.

The film layer 250 is disposed between the substrate 210 and the anode 220 to improve the internal light extraction efficiency of the light emitted from the organic light emitting layer 230. In other embodiments, the film layer 250 may be coated on a bottom surface of the substrate 210 of FIG. 5 for improving the external light extraction efficiency of the organic electroluminescent device.

A visible ray-refractive index of the organic light emitting layer 230 may be varied depending on a wavelength of light and may have a range of about 1.6 to 1.9. Since the ITO used of the anode 220 has a refractive index within a range of about 1.9 to 2.0, the generated light may be transmitted from the medium (i.e., the organic light emitting layer 230) having a low refractive index to the medium (i.e., the anode 220) having a high refractive index, so that the total-reflection may hardly occur at the interface between the organic light emitting layer 230 and the anode 220. However, if the glass or plastic generally used in the substrate 210 has a refractive index of about 1.5 and each of the organic light emitting layer 230 and the anode 220 has a thin thickness within a range of 100 nm to 400 nm, the light generated from the organic light emitting layer 230 may be mostly converted into the guided mode light not to be outputted to the outside of the organic electroluminescent device. For preventing this phenomenon, the film layer 250 having the function of the light scattering layer is disposed between the substrate 210 and the anode 220.

The film layer 250 has a refractive index equal to or greater than that of the organic light emitting layer 230 by the high refractive material chemically combined with the polymer matrix. Additionally, the film layer 250 includes the low refractive material chemically combined with the polymer matrix and having the lower refractive index than the high refractive material. The film layer 250 may be the optical film described above.

Since the high refractive material of the film layer 250 has the refractive index equal to or greater than that of the organic light emitting layer 230 and is chemically combined with a film base (e.g., the polymer matrix), the light emitted from the organic light emitting layer 230 may be effectively inputted into the film layer 250.

The light inputted into the film layer 250 is scattered by the low refractive material having the lower refractive index than the high refractive material to minimize the guided mode light caused at the film layer 250 and the substrate 210.

As a result, the light extraction efficiency of the organic electroluminescent device may be improved. Additionally, for more improving the light extraction efficiency, the low refractive material may be separated from the polymer matrix of the film layer 250. For example, the low refractive material of the film layer 250 may be separated from the polymer matrix by the thermal treating process. The high refractive material may not be separated from the polymer matrix during the thermal treating process. In this case, the film layer 250 may include a high refractive matrix 251 (i.e., the polymer matrix including the high refractive material) and low refractive particles 253 dispersed within the high refractive matrix 251. For example, if the polymer matrix is polyamic acid being the precursor of polyimide, the high refractive material may be chemically combined with the diamine of the polyamic acid and the low refractive material may be chemically combined with the carboxylic acid of the dianhydride in the polyamic acid. During the thermal treating process, polyamic ester may be converted into polyimide and only the low refractive material may be separated from the polymer matrix. The combining state of the high refractive material may maintain in the polyimide. To achieve this, a process temperature of the thermal treating process may be equal to or greater than the temperature at which the low refractive material is separated from the polymer matrix and be less than the temperature at which the high refractive material is separated from the polymer matrix.

According to the organic electroluminescent device of the inventive concept, the film layer may be deposited on the substrate and then one thermal treating process may be performed on the deposited film layer to form the light scattering layer. Thus, it is possible to simplify a method of manufacturing the organic electroluminescent device. Additionally, the high and low refractive materials are chemically combined with the polymer matrix (not physical combination). Thus, the film layer 250 may be easily treated, and the high and low refractive materials may be uniformly distributed throughout the film layer 250 by the chemical combination properties.

As described above, the high refractive material may be chemically combined with the diamine part of the polyamic acid and the low refractive material may be chemically combined with the carboxylic acid of the dianhydride part in the polyamic acid, so that the optical film may be easily manufactured.

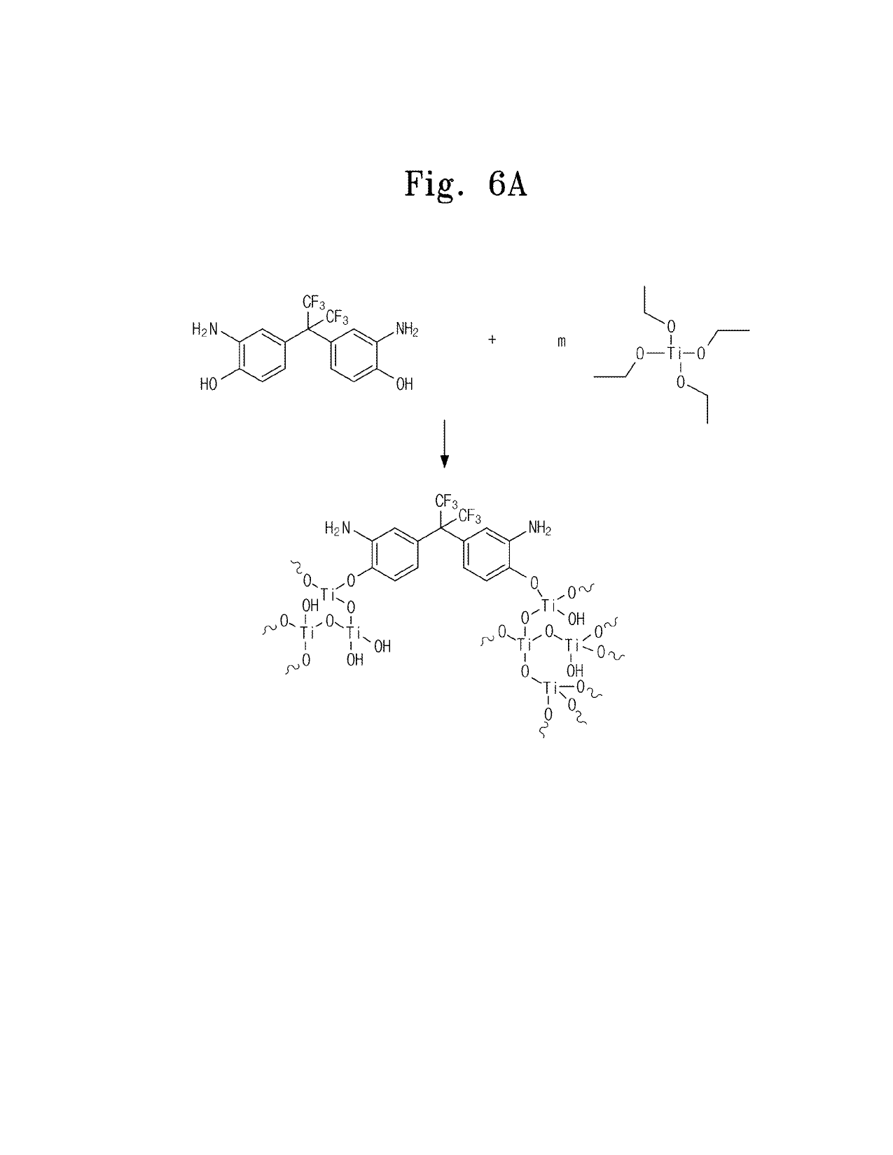

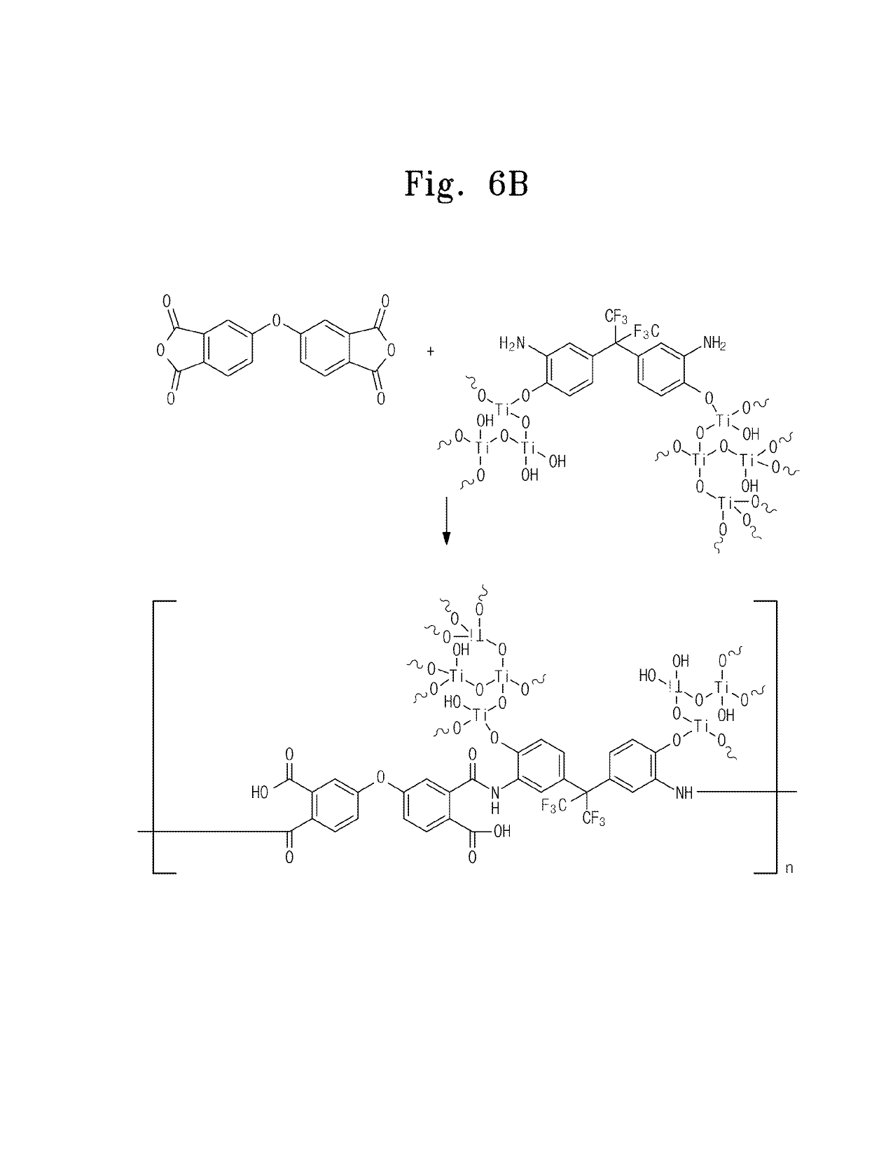

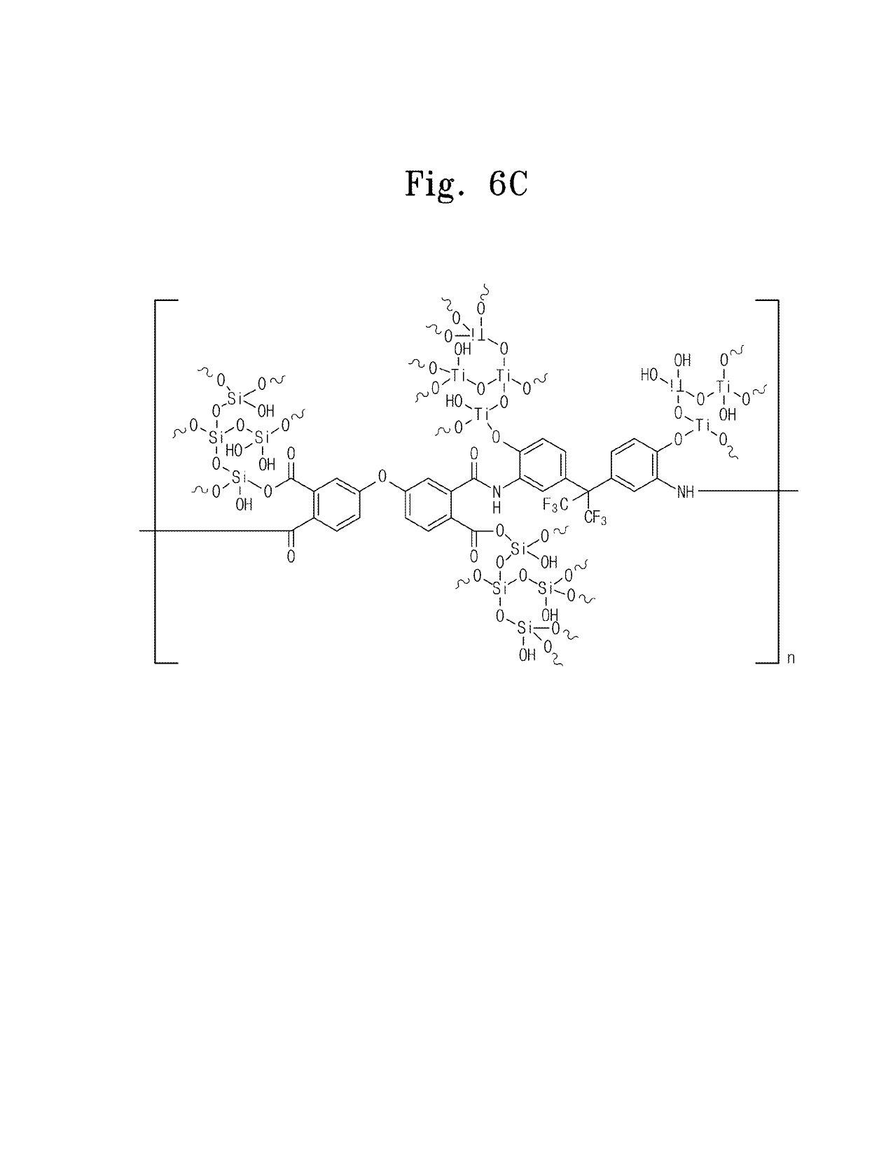

FIGS. 6A to 6B are schematic views illustrating a method of manufacturing a polymer for an optical film according to embodiments of the inventive concept.

Firstly, referring to FIG. 6A, the high refractive material is chemically combined with the diamine. Thus, it is possible to generate diamine monomers with which the high refractive material including TiO₂ is combined. Here, “m” is a real number greater than 0.

Next, referring to FIG. 6B, the diamine monomers are polymerized with dianhydride to form polyamic acid. Here, “n” has a range of 1 to 1000.

Referring to FIG. 6C, the low refractive material having the lower refractive index than the high refractive material may be chemically combined with the carboxylic acid of the dianhydride in the polyamic acid, thereby forming the polymer for the optical film. The low refractive material may include SiO₂. Synthesis of the polymer may be performed in a solvent including at least one of N, N-dimethyl acetamide (DMAc), N, N-dimethyl formamide (DMF), N-methyl pyrrolidine (NMP), cyclopentanone, cyclohexanone, and γ-butyrolactone. The polymer solution may filter and then spin-coated. The solvent in the spin-coated polymer solution may be removed to form the optical film. The separation of the low refractive material may be performed at a temperature of about 200° C. or more, and the separation of the high refractive material may be performed at a temperature of about 400° C. or more. Thus, the removal of the solvent and the separation of the low refractive material may be performed at a temperature within a range of about 200° C. to about 400° C. in a substantially vacuum or in atmospheric pressure.

As described above, the optical film formed of the polymer of the inventive concept includes the high refractive material having the refractive index equal to or greater than that of the organic light emitting layer. Thus, the guided mode light may be minimized. Additionally, the optical film further includes the low refractive material, so that it may function as the light scattering layer.

Furthermore, the low refractive material may be dispersed in the high refractive film by one thermal treating process in the process of manufacturing the optical film. Thus, light input efficiency and the light scattering efficiency may be improved and the manufacturing process of the optical film may be simplified.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A polymer comprising:
a polymer matrix;
a high refractive material chemically combined with the polymer matrix; and
a low refractive material chemically combined with the polymer matrix and having a lower refractive index than the high refractive material,
wherein all of the low and high refractive materials are chemically combined with the polymer matrix.

2. An optical film comprising:
a polymer matrix;
a high refractive material chemically combined with the polymer matrix; and
a low refractive material chemically combined with the polymer matrix and having a lower refractive index than the high refractive material,
wherein all of the low and high refractive materials are chemically combined with the polymer matrix.

3. The optical film of claim 2, wherein the low refractive material is separated from the polymer matrix at a temperature lower than a temperature at which the high refractive material is separated from the polymer matrix.

4. The optical film of claim 2, wherein the high refractive material includes at least one of TiO₂, ZrO₂, ZnO, SnO₂, In₂O₃, and In₂O₃—SnO₂.

5. The optical film of claim 2, wherein the low refractive material includes SiO₂.

6. The optical film of claim 2, wherein the polymer matrix includes polyamic acid.

7. The optical film of claim 6, wherein the high refractive material is chemically combined with diamine of the polyamic acid being a precursor of polyimide; and
wherein the low refractive material is chemically combined with carboxylic acid of dianhydride in the polyamic acid.

8. An optical film including a material expressed as chemical formula 1, 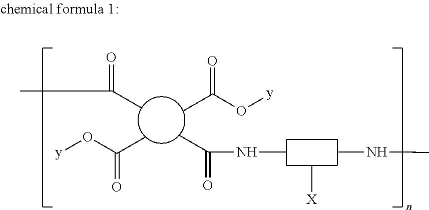
wherein “x” denotes a high refractive material, “y” denotes a low refractive material having a lower refractive index than the high refractive material, and “n” has a range of 1 to 1000.

9. The optical film of claim 8, wherein a separating temperature of the x is lower than a separating temperature of the y.

10. The optical film of claim 8, wherein the x has an inorganic metal oxide transformed from a compound having a structure expressed as chemical formula 2; 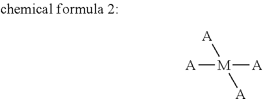
wherein “A” denotes an alkoxide group capable of being transformed into a hydroxide group by water; and
wherein “M” includes one of Ti, Zr, Zn, Sn, and In.

11. The optical film of claim 8, wherein the y has an inorganic metal oxide transformed from a compound having a structure expressed as chemical formula 3; 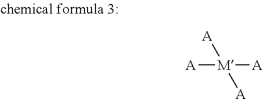
wherein “A” denotes an alkoxide group capable of being transformed into a hydroxide group by water; and
wherein “M′” is Si.

12. An organic electroluminescent device comprising:
an organic light emitting layer; and
a film layer increasing light extraction efficiency of light emitted from the organic light emitting layer,
wherein the film layer includes a high refractive material and a low refractive material;
wherein the high refractive material is chemically combined with a polymer matrix and has a refractive index equal to or greater than a refractive index of the organic light emitting layer; and
wherein the low refractive material is chemically combined with the polymer matrix and has a refractive index lower than the refractive index of the high refractive material.

13. The organic electroluminescent device of claim 12, wherein the low refractive material of the film layer is separated from the polymer matrix by a thermal treating process performed after coating the film layer.

14. A method of manufacturing an optical film, comprising:
chemically combining a high refractive material with diamine in polyamic acid being a precursor of polyimide; and
chemically combining a low refractive material having a lower refractive index than the high refractive material with carboxylic acid of dianhydride in the polyamic acid.

15. A method of manufacturing an optical film, comprising:
chemically combining a high refractive material with diamine;
reacting the diamine with dianhydride to form a polymer; and
chemically combining a low refractive material having a lower refractive index than the high refractive material with carboxylic acid of a dianhydride part of polyamic acid being the polymer.
